(19) United States
(12) Patent Application Publication
(10) Pub. No.: US 2009/0236716 A1
(43) Pub. Date: Sep. 24, 2009

(54) RECTIFYING DIODE PACKAGE STRUCTURE

(76) Inventor: Wen-Huo Huang, Hsinchu County (TW)

Correspondence Address: Muncy, Geissler, Olds & Lowe, PLLC, P.O. BOX 1364, FAIRFAX, VA, 22038-1364, US

(21) Appl. No.: 12/406,782

(22) Filed: Mar. 18, 2009

(30) Foreign Application Priority Data
Mar. 20, 2008 (TW) 097109753

(51) Int. Cl. H01L 23/02

(52) U.S. Cl. 257/678; 257/E23.18

(57) ABSTRACT

A rectifying diode package structure includes a base which has a holding deck to hold a diode chip and a protective portion on the perimeter of the base to form sealing space filled by a filling material to seal the diode chip in an integrated manner. The diode chip has a conductive element extended outside the sealing space. The holding deck and the protective portion are interposed by a buffer ring embedded in the filling material. The buffer ring has at least one retaining ridge which has at least one first end and one second end of different cross sections formed in an upright manner to form a retaining relationship between the buffer ring and the filling material.

### FIELD OF THE INVENTION

The present invention relates to a rectifying diode and particularly to a rectifying diode package structure.

### BACKGROUND OF THE INVENTION

Solid state diodes are widely used on a lot of electronic devices. Each solid state diode has a positive terminal and a negative terminal corresponding to each other. Voltage and current presented between them have non-linear characteristics. One type of diode has one way conductive characteristic, and can transform AC power to DC power to achieve rectification effect so that a power supply can output steady DC power. Such type of diode also is called rectifying diode or rectifier. It has been adopted in a wide variety of applications, such as information, communication, consumer electronic, aviation and space exploration, medical, motor vehicles, business equipment and the like.

The basic structure of the conventional rectifying diode, such as U.S. Pat. Nos. 5,005,069, 5,886,403 and 6,362,546, includes a base, a diode chip mounted onto the base, and an electrode connecting to another side of the diode chip. The diode chip and electrode are sealed through an insulating filling material to provide protection of the connection of the diode chip and electrode. Although the diode chip gets some protection from the encased filling material, during installation of the rectifying diode on a rectification board, it still could receive pressure from the rectification board and result in deformation or fracture. In order to enhance protection of the sealed chip, many improved techniques have been proposed. References can be found in U.S. Pat. Nos. 6,060,776, 6,667,545, 6,958,530, 7,009,223 and 2007105454. They mostly have a base surrounded by an integrated protective wall or sleeve to resist external pressure so that the filling material does not directly receive pressure from the rectification board. But they still cannot fully eliminate the external pressure from transmitting to the diode chip caused by press-fit relationship. And deformation or damage of the diode chip could still occur. China patent application No. CN1879212A discloses a technique of encasing the diode chip with resin and surrounding the resin with a protective sleeve. The perimeter of the protective sleeve perimeter and the base are spaced by a gap. However, the gap creates a height limitation on the edge structure when the protective sleeve is installed by press-fit. This results in an undesirable anchoring of the protective sleeve. Hence there are still rooms for improvement, especially on providing a desired package environment for the diode chip and increasing the life span thereof.

### SUMMARY OF THE INVENTION

The primary object of the present invention is to effectively release the external pressure of a rectifier chip and prevent deformation or damage of the chip. To achieve the foregoing object, the present invention provides a rectifying diode package structure which has a base including a holding deck to hold a diode chip and a protective portion formed on the perimeter of the base. The protective portion has a sealing space filled by a filling material to seal the diode chip in an integrated manner. The diode chip has a conductive element extended outside the sealing space. The holding deck and the protective portion are interposed by a buffer ring embedded in the filling material. The buffer ring has at least one retaining ridge formed with at least a first end and a second end of different cross sections in an upright manner so that a retaining relationship is formed between the buffer ring and the filling material.

In one embodiment, a first pressure-release trench is formed between the holding deck and the protective portion to prevent moisture from seeping into the sealing space through a gap formed between the protective portion and the filling material. A second pressure-release trench can also be formed at the bottom of the base opposite to the first pressure-release trench.

In another embodiment, the holding deck has a protrusive ring formed on the perimeter in a diagonal manner to wedge in the filling material to prevent the filling material from breaking away from the sealing space when subject to drawing or squeezing of the external force.

By providing the buffer ring between the holding deck and the protective portion, when the rectifying diode package structure of the invention is compressed by the external force, the buffer ring can release a great amount of pressure to protect the diode chip on the base without deforming or damaging. In addition, the stress-release trench formed between the holding deck and the protective portion can incorporate with the buffer ring to release the external pressure force. Such a structure also can prevent moisture from seeping through the gap formed between the protective portion and the filling material to contact the diode chip. Thus the diode chip can function normally as desired. The protrusive ring can wedge in the filling material to make the entire rectifying diode package structure firmer.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a perspective view of a first embodiment of the invention.

FIG. 2 is an exploded view of the first embodiment of the invention.

FIG. 3A is a sectional view of the first embodiment of the invention.

FIG. 3B is a fragmentary enlarged view of the first embodiment of the invention.

FIG. 4A is a sectional view of a second embodiment of the invention.

FIG. 4B is a fragmentary enlarged view of the second embodiment of the invention.

FIG. 5 is a fragmentary enlarged view of a third embodiment of a buffer ring of the invention.

FIG. 6 is a fragmentary enlarged view of a fourth embodiment of a buffer ring of the invention.

FIG. 7 is a schematic cross section of an embodiment of a first end of the retaining ridge of the buffer ring.

FIG. 8 is a schematic cross section of another embodiment of a first end of the retaining ridge of the buffer ring.

FIG. 9 is an exploded view of yet another embodiment of the invention.

### DETAILED DESCRIPTION OF THE PREFERRED EMBODIMENTS

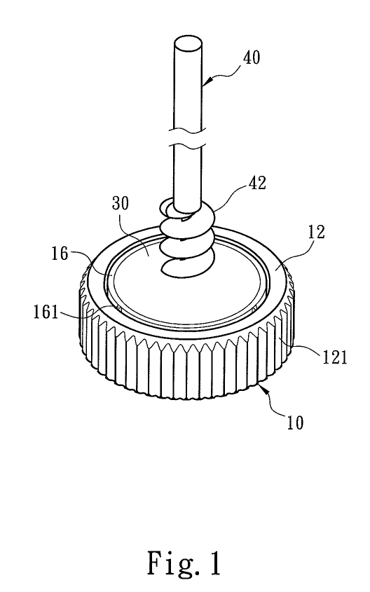

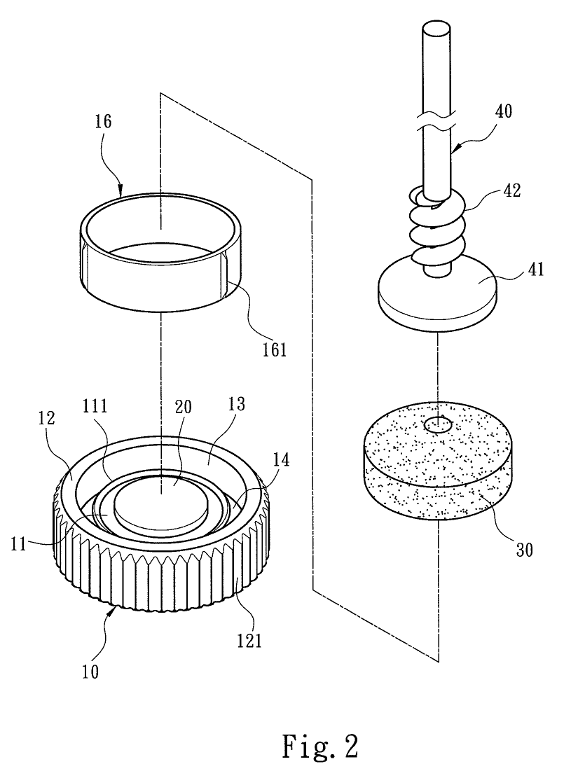

Please refer to FIGS. 1 through 3B for a first embodiment of the invention. The present invention provides a rectifying diode package structure which has a base 10. The base 10 has a holding deck 11 to hold a diode chip 20 and a protective portion 12 formed on the perimeter of the base 10. The protective portion 12 has a plurality of jutting ridges 121 formed on an outer surface and a sealing space 13 inside filled by a filling material 30 (such as epoxy resin or silicone gel and the like) to seal the diode chip 20 in an integrated manner. As the base 10 and the filling material 30 are made from different materials, during packaging process, the filling material 30 and the base 10 have different degrees of expansion or retraction, and a gap or infirm fitting could form between them. In this embodiment, a protrusive ring 111 is formed on the perimeter of the holding deck 11 in a diagonal manner to wedge in the filling material 30. Hence it is to prevent the filling material 30 from breaking away the sealing space 13 when subject to external squeezing or drawing. And the diode chip 20 on the holding deck 11 can be maintained and sealed in the filling material 30. The diode chip 20 has a conductive element 40 extended outside the sealing space 13 to form electric connection with an electronic device. The conductive element 40 has a conductive root 41 connecting to the diode chip 20, and an elongate stem connecting to the electronic device that might be deformed or broken due to excessive drawing or twisting caused by external force. To remedy this problem, the conductive element 40 has an elastic section 42 to absorb the external force from different directions. The elastic section 42 may be formed in a helical or bend-neck fashion.

When the protective portion 12 receives the external force, the external force could be transmitted through the filling material 30 to the diode chip 20. A first pressure-release trench 14 located between the holding deck 11 and the protective portion 12, and even a second pressure-release trench 15 located at the bottom of the base 10 opposite to the first pressure-release trench 14, provides a shock-absorbing effect for the diode chip 20.

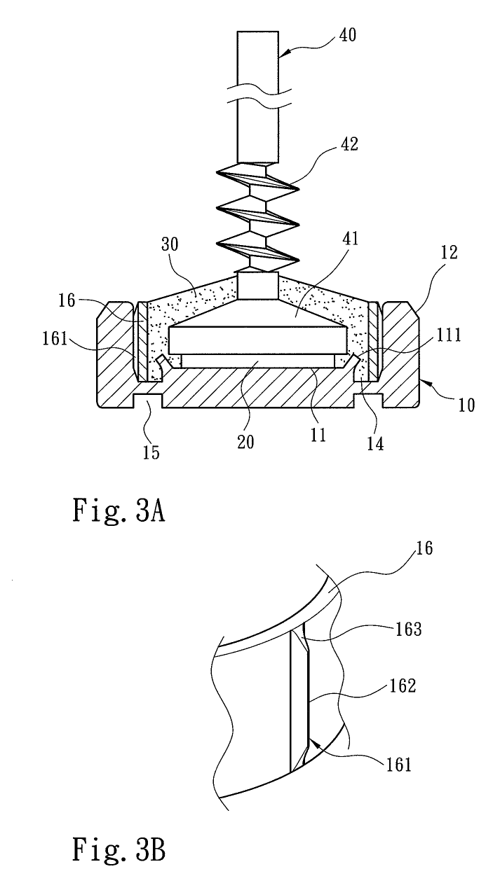

In addition, there is a buffer ring 16 interposed between the holding deck 11 and the protective portion 12 and embedded in the filling material 30 to isolate the external force from directly transmitting from the protective portion 12 through the filling material 30 to the diode chip 20. By incorporating the buffer ring 16 with the protective portion 12 and the first and second pressure-release trenches 14 and 15, the diode chip 20 can get sufficient protection. To prevent the buffer ring 16 from separating from the filling material 30 by shaking or drawing, referring to FIG. 3B, the buffer ring 16 further has at least one retaining ridge 161 which has at least one first end 162 and one second end 163 formed in an upright manner with different cross sections. The retaining ridge 161 is wedged in the filling material 30 with the first and second ends 162 and 163 form a cubical hindrance so that the buffer ring 16 can be securely retained in the filling material 30.

In this embodiment, the cross section of the first end 162 is larger than the second end 163. The first end 162 is located in the center of the retaining ridge 161, while the second end 163 is located respectively at two sides of the retaining ridge 161, thus substantially form a shuttle shape. When the buffer ring 16 sealed in the filling material 30 and the retaining ridge 161 wedged in the filling material 30, the buffer ring 16 can be securely held in the filling material 30 without turning or moving. Moreover, with the first end 162 of the retaining ridge 161 formed a cross section larger than the second end 163 and embedded in the filling material 30, vertical movement of the buffer ring 16 relative to the filling material 30 can be prevented. Thus the buffer ring 16 retained in the filling material 30 not only can prevent relative movement between them, also can prevent separation thereof.

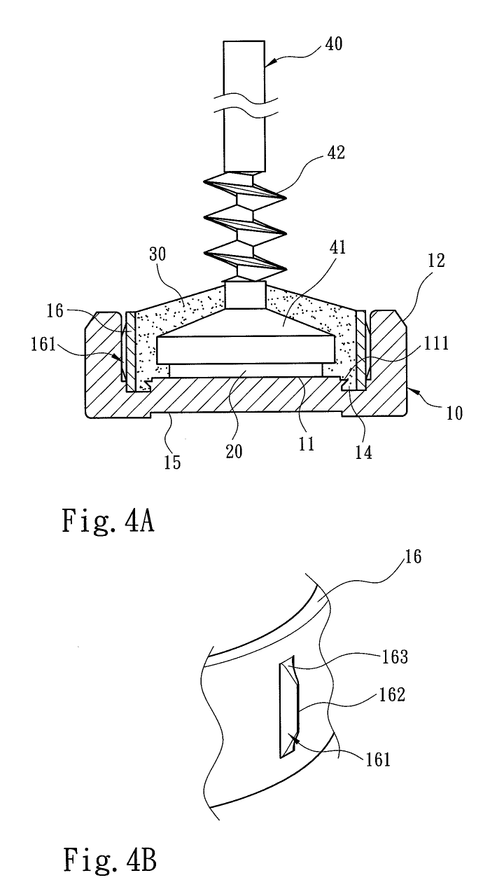

Refer to FIGS. 4A and 4B for a second embodiment of the invention. It differs from the first embodiment previously discussed by having a horizontal protrusive ring 111 formed on the perimeter of the holding deck 11 to wedge in the filling material 30. The base 10 has a second pressure-release trench 15 at the bottom extended outwards from the center. It also has the retaining ridge 161 the same as the first embodiment, but may be at the different length (referring to FIG. 4B). The protrusive ring 111, second pressure-release trench 15 and retaining ridge 161 provide functions the same as the first embodiment.

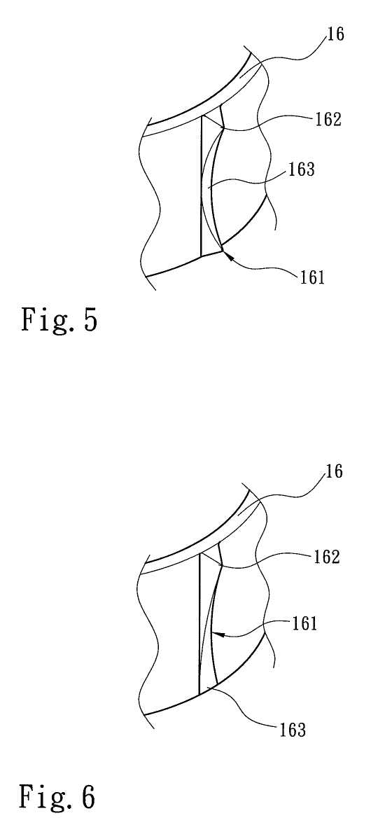

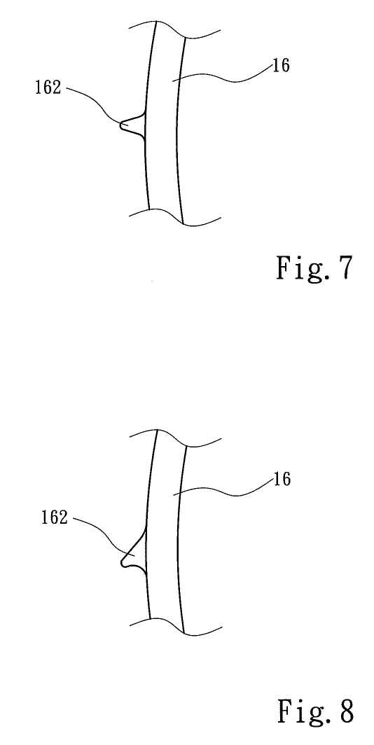

The buffer ring 16 may be formed in varying embodiments. FIG. 5 illustrates another one in which the first end 162 is respectively located at two sides of the retaining ridge 161, while the second end 163 is located in the center of the retaining ridge 161. As shown in FIG. 6, the first end 162 and second end 163 are respectively located at two sides of the retaining ridge 161 and form a conical fashion. In addition, the first end 162 may also be formed in various profiles. As shown in FIG. 7, the first end 162 has a jutting cross section in a symmetrical manner. As shown in FIG. 8, the first end 162 jutting to form an asymmetrical cross section. With the buffer ring 16 formed in a desired profile as previously discussed, it can be firmly wedged in the filling material 30 to prevent movement or separation from the filling material 30.

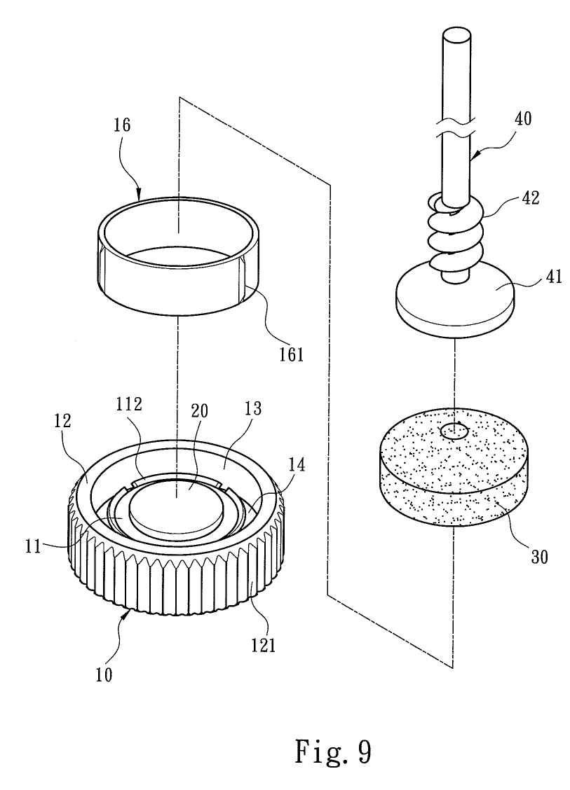

Refer to FIG. 9. It has a plurality of arched flanges 112 formed on the perimeter of the holding deck 11 and spaced from each other in a diagonal or horizontal manner. The arched flanges 112 equally located on the perimeter of the holding deck 11 to serve the function of the protrusive ring 111 to form a secured bonding with the filling material 30 without separating when subject to squeezing or drawing of the external force. Therefore, the diode chip 20 mounted onto the holding deck 11 can be securely sealed in the filling material 30.

As a conclusion, the rectifying diode package structure of the invention provides a buffer ring 16 between the protective portion 12 and holding deck 11 and sealed in the filling material 30 in an integrated manner, thus can effectively resist the pressure transmitted to the filling material 30 from the protective portion 12, and provide improved protection for the diode chip 2. The invention further provides at least one retaining ridge 161 wedged in the filling material 30 to form retaining of the buffer ring 16 in the filling material 30 so that the buffer ring 16 can be firmly held in the filling material 30 without moving or separating when subject to the external force or twisting. The whole structure can be maintained intact. It provides a significant improvement over the conventional techniques.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A rectifying diode package structure comprising a base which has a holding deck to hold a diode chip and a protective portion located on the perimeter of the base to form a sealing space to hold a filling material to seal the diode chip in an integrated manner, the diode chip having a conductive element extended outside the sealing space, characterized in that:
the holding deck and the protective portion are interposed by a buffer ring embedded in the filling material, the buffer ring having at least one retaining ridge which has at least one first end and one second end formed thereon in an upright manner at different cross sections such that a relative retaining relationship is formed between the buffer ring and the filling material.

2. The rectifying diode package structure of claim 1, wherein the first end has a cross section larger than the second end.

3. The rectifying diode package structure of claim 2, wherein the first end is respectively located at two sides of the retaining ridge and the second end is located in the center of the retaining ridge.

4. The rectifying diode package structure of claim 2, wherein the first end is located in the center of the retaining ridge and the second end is respectively located at two sides of the retaining ridge.

5. The rectifying diode package structure of claim 2, wherein the first end and the second end are respectively located at two sides of the retaining ridge.

6. The rectifying diode package structure of claim 2, wherein the first end is formed with a protrusive cross section of equilateral sides.

7. The rectifying diode package structure of claim 2, wherein the first end is formed with a protrusive cross section of non-equilateral sides.

8. The rectifying diode package structure of claim 1 further having a first pressure-release trench located between the holding deck and the protective portion.

9. The rectifying diode package structure of claim 8, wherein the base has a second pressure-release trench formed at the bottom thereof corresponding to the first pressure-release trench.

10. The rectifying diode package structure of claim 1, wherein the holding deck has a protrusive ring formed on the perimeter thereof in a diagonal manner.

11. The rectifying diode package structure of claim 1, wherein the holding deck has a plurality of arched flanges formed on the perimeter thereof in a diagonal manner and spaced from each other.

12. The rectifying diode package structure of claim 1, wherein the holding deck has a protrusive ring formed on the perimeter thereof in a horizontal manner.

13. The rectifying diode package structure of claim 1, wherein the holding deck has a plurality of arched flanges formed on the perimeter thereof in a horizontal manner and spaced from each other.

14. The rectifying diode package structure of claim 1, wherein the conductive element has a conductive root connecting to the diode chip.

15. The rectifying diode package structure of claim 1, wherein the conductive element has an elastic section.

16. The rectifying diode package structure of claim 1, wherein the protective portion has a plurality of jutting ridges formed on the annular surface thereof.
